(19) United States
(12) Patent Application Publication
(10) Pub. No.: US 2004/0107986 A1
(43) Pub. Date: Jun. 10, 2004

(54) High throughput microcalorimeter systems and methods

(76) Inventors: Andy C. Neilson, Groton, MA (US); Jay S. Teich, Weston, MA (US); Mike R. Sweeney, Stoneham, MA (US)

Correspondence Address: TESTA, HURWITZ & THIBEAULT, LLP, HIGH STREET TOWER, 125 HIGH STREET, BOSTON, MA, 02110, US

(21) Appl. No.: 10/313,917

(22) Filed: Dec. 6, 2002

(51) Int. Cl. H01L 35/30; H01L 35/28

(52) U.S. Cl. 136/204; 136/205

(57) ABSTRACT

A system is provided to enable high throughput parallel processing of multiple samples for drug screening methods and other analytical methods. Disposable wellplates cooperate with external sensor arrays to eliminate the laborious task of cleaning and sterilizing contaminated system components. The wellplates can use conventional or custom array formats, and are adapted and configured to be well suited for high throughput automated analytical screening processes.

### FIELD OF THE INVENTION

The present invention relates generally to calorimetry and particularly to monitoring chemical and physiological processes by measuring thermodynamic activity in multi-well sample plates , using a sample container that may be removed from the apparatus.

### BACKGROUND

Heat can be a useful, measurable indicator of various chemical and physiological processes. The measurement of heat provides a signal that may be directly correlated to chemical reactions, or to metabolic activity and certain cellular functions within living organisms. For example, in a living organism, heat is a byproduct of cellular respiration. The oxidation of glucose within a cell releases about 2,875 kiloJoule/mole (kJ/mol) of energy. This portion of this energy released as heat may raise the temperature of a surrounding medium, thereby allowing measurement with a thermal sensor and enabling quantification of metabolic activity.

A number of methods may be used to measure the heat produced by a chemical or biological reaction within a contained sample volume. These methods include the use of contact temperature sensors such as thermometers, thermo-electrical sensors including thermistors, resistance temperature detectors (RTDs) and platinum resistance thermometers (PRTs), or thermo-mechanical sensors whose properties are monitored by capacitance or resistance sensors, or non-contact methods using infrared optical sensors.

The measurement of heat produced by biological processes, such as cellular respiration, requires extremely high thermal sensitivity. Commercially available microcalorimeters are typically able to resolve reactions producing less than one microwatt of heat per milliliter sample volume, sufficient to monitor cellular respiration in many cell systems.

It would be useful to apply microcalorimetry to the problem of screening of large numbers of chemical entities for their effect on heat production. One such example would be the screening of large numbers of catalysts for their effects on various substrates. Another example would be the screening of large numbers of chemical agents for their effect on cellular metabolism. In these examples, a microcalorimeter containing one or a few sample chambers would not provide the means to screen large numbers of reactions in a reasonable time period. Furthermore, many microcalorimeters lack removable sample chambers that can be cleaned, or disposed of, to prevent contamination. Previous attempts to scale-up microcalorimeters to accommodate larger numbers of simultaneous measurements have resulted in inadequate sensitivity and insufficient throughput for the demands of screening applications.

Accordingly, there exists a need for a highly sensitive sensor apparatus for accurately and efficiently monitoring the heat produced by a large number of simultaneous chemical or biological processes.

### SUMMARY

A thermistor is a semiconductor device that exhibits relatively large changes in resistance as a function of temperature. The very high gain (>4%/° C.) of thermistors enables them to resolve very small changes in temperature in a given temperature range. Thermistor and thermistor arrays may be used to measure the heat produced by biological reactions using immersion techniques in which the thermistor is in direct contact with the assay. In other applications, a thermistor may be used as an integral part of a Dewar flask. Although both of these methods have utility for thermal measurement, they are not well suited for high throughput processes because of the required cleaning and sterilization of the sensor apparatus between measurements of different assays.

Thermocouples are bimetallic sensors that produce an electrical potential difference proportional to the temperature difference between two surfaces. A thermopile is a multi-layer thermocouple device. A thermopile has high thermal conductivity between its two surfaces and can therefore be used to measure heat flow through the device, i.e., from one surface to the other. When one surface of a thermopile is attached to a constant temperature heat sink, and the other surface is attached to a heat-producing sample that is otherwise isolated from the environment, an electrical measurement of the heat produced by the sample can be made. The quality of such a measurement can be further improved by providing measurable, negative electrical feedback to the thermopile to drive its potential difference, and temperature difference, close to zero.

Thermopiles may be used to measure the heat produced by a chemical or biological reaction by measuring the heat flow from a sample, through a sensor, to a thermal sink. A microcalorimeter typically will incorporate a thermopile sensor sandwiched between a sample chamber and a thermostated heat sink. While high sensitivity measurements can be made with such a device, this method has not be shown to be compatible with multiple, removable, and particularly, disposable sample containers due in part to the difficulty of ensuring a high thermal conductivity connection between a removable, multiple sample chamber and a heat-flow sensor.

According to the inventions, apparatus and methods are provided for measuring the heat produced by chemical and physiological reactions by using microcalorimetry in a manner consistent with the requirements of modern drug screening methods and other analytical methods.

More specifically, a system is provided to enable high throughput parallel processing of multiple samples. Disposable wellplates cooperate with external sensor arrays to eliminate the laborious task of cleaning and sterilizing contaminated system components. The wellplates can use conventional or custom array formats, and are adapted and configured, according to the invention, to be well suited for high throughput automated analytical screening processes.

In an aspect, the invention features a wellplate that includes a plurality of wells, each well including a sidewall and an end wall adapted to receive a material therein. At least one of the sidewall and the end wall of at least one well comprises a mating exterior surface adapted to mate with a thermal sensor, thereby enabling precise thermal measurement of a sample contained in the well, and the plurality of wells is adapted to mate with a plurality of thermal sensors.

One or more of the following features may be included. The mating surface of the at least one well may include a contoured surface. The mating surface comprises a depression. The depression may be substantially uniform about an axis of rotation extending through the depression. The mating surface may be compliant and able to adapt to a surface of a mating sensor. The wellplate may be disposable. The wellplate may include a microtiter wellplate. A thermal isolator may be disposed proximate the at least one well, the thermal isolator being adapted to thermally isolate the at least one well from a proximate well. The thermal isolator may be air, xenon, argon, carbon dioxide, vacuum, vacuum beads, or combinations thereof.

The wellplate may include a baseplate and a cover plate. At least one of the baseplate and the cover plate may form at least one channel in fluidic communication with at least one well.

A thickness of the at least one of the sidewall and end wall having a mating surface may be less than a thickness of a remainder of the at least one well. A thermal conductivity of the at least one of the sidewall and end wall having a mating surface may be greater than a thermal conductivity of a remainder of the at least one well.

An interior surface of the at least one well comprises a material supporting cell adhesion, such as a polymer. A coating may be disposed on an inner surface of the at least one well, the coating including a material promoting cell adhesion, such as polylysine, a collagen material, or a basement membrane protein.

The wellplate may be substantially rectangular. The plurality of wells may include an array of wells. The array of wells may include a number of wells selected from the group consisting of 24, 96, 384, 768, 1536, 3456, and 9600. A density of sample wells in the wellplate may be at least about one well per 81 mm². The plurality of wells may include a strip of wells. The strip of wells may include a number of wells, such as 8 or 12 wells. A volume of each well may be less than about 500 microliters.

In another aspect, the invention features an apparatus for monitoring a temperature of a material. The apparatus includes a wellplate having a plurality of wells for containing the material, with at least one well having a compliant mating surface. The apparatus also includes at least one sensor having a complementary surface for mating with at least a portion of the mating surface of the at least one well, with the sensor being adapted to monitor the temperature of the material in the at least one well.

One or more of the following features may be included. The at least one well may be biased against the sensor by a pressure differential. The at least one sensor may be a thermistor, a platinum resistance thermometer (PRT), a resistance temperature detector (RTD), a diode, or a transistor. The apparatus may include at least one component having a high thermal resistance, with the at least one sensor being disposed between the mating surface and the at least one component, and the at least one component thermally isolates the at least one sensor from thermal ground.

The at least one sensor may include a thermopile. The apparatus may include a heat sink, with the at least one thermopile contacting the heat sink.

The mating surface of the at least one well may include a depression. The at least one well may include a thin wall portion. The thin wall portion may have a thickness less than about 0.01 inches. The at least one well may include a material supporting cell adhesion. The at least one well may include a polymer. A coating may be disposed on an inner surface of the at least one well, the coating including a material promoting cell adhesion, such as polylysine, a collagen material, or a basement membrane protein.

In another aspect, the invention features a method for monitoring a temperature of a material, the method including providing a well for containing the material, the well including an external mating surface. The material is placed into the well. At least a portion of the external mating surface of the well is contacted with a sensor having a complementary mating surface for mating with the mating surface of the well. The temperature of the material in the well is determined, based at least in part on an output of the sensor.

One or more of the following features may be included. The sensor may be a thermistor, a PRT, an RTD, a diode, or a transistor. The sensor may include a thermopile attached at one end to a heat sink. A medium may be provided proximate the contact between the sensor and the well for reducing thermal resistance between the sensor and the well. The medium may include thermal grease, such as aluminum thermal grease and silver filled thermal grease. A medium may be provided proximate the sensor and the well for thermally isolating the sensor and the well from ambient. The medium may be air, xenon, argon, carbon dioxide, vacuum, vacuum beads, and combinations thereof.

In another aspect, the invention features a system for monitoring temperatures in a plurality of wells in a wellplate, each well including a sidewall and an end wall adapted to receive a material therein, at least one of the sidewall and the end wall having a mating exterior surface adapted to mate with a sensor. The system includes a plurality of sensors adapted to mate with the mating exterior surfaces of the wells, a processing chamber adapted to receive the wellplate and to position the sensors to mate with the mating exterior surfaces of the wells, a handling system configured to transport the wellplate to and from the processing chamber, and a processor configured to control movement of the wellplate and to receive signals from the sensors.

One or more of the following features may be included. The wellplate may include an array of wells. A loading station may be adapted to hold the wellplate prior to transport of the wellplate to the processing chamber. An unloading station may be adapted to hold the wellplate subsequent to transport of the wellplate from the processing chamber. A user interface may be connected to the processor.

In another aspect, the invention features an apparatus for detection of changes of temperature in each of a plurality of wells in a wellplate, the wells adapted for receiving test samples and comprising respective thermally conductive portions. The apparatus includes a sensor array for sensing temperature, the sensor array including a base for supporting a plurality of sensors positionable in thermal communication with the wells. The apparatus also includes a registration structure for facilitating mating of the wellplate and the sensor array so as to register respective thermal sensors with respective wells of the wellplate, thereby to obtain data indicative of temperature changes in respective wells by detecting heat conducted through the thermally conductive portions.

One or more of the following features may be included. A thermal insulator may be disposed between the wells to minimize heat transfer from a well to a sensor registered with a different well. A thermal insulator may be disposed between the sensors to minimize heat conductance from a well to a sensor registered with a different well. A handling system may be configured for transporting the wellplate to and from the sensor array. An automated fluid delivery system for filling the wells in the wellplate may be provided. A processor may be in communication with the sensors, the processor configured to receive signals indicative of temperature changes in the wells.

### BRIEF DESCRIPTION OF THE DRAWINGS

The following drawings are not necessarily to scale, emphasis instead being placed generally upon illustrating the principles of the invention. The foregoing and other features and advantages of the present invention, as well as the invention itself, will be more fully understood from the following description of exemplary and preferred embodiments, when read together with the accompanying drawings, in which:

FIGS. 1a-1b are schematic cross-sectional and top views of a well in accordance with one embodiment of the invention;

FIGS. 1c-1f are schematic cross-sectional views of wells in accordance with various alternative embodiments of the invention;

FIGS. 2a-2b are schematic top views of wellplates with pluralities of wells filled with assay material;

FIG. 3a is a schematic cross-sectional view of a thermistor used in a system in accordance with one embodiment of the invention;

FIGS. 3b-3e are schematic views of other thermistors that can be used with various alternative embodiments of the invention;

FIG. 4 is a schematic view of a thermistor mounted on a thermal isolation structure;

FIGS. 5a-5c are schematic cross-sectional views of thermistors in contact with various wells;

FIG. 6 is a graph illustrating exemplary temperature measurements as a function of time of a wellplate and sensor configuration in accordance with one embodiment of the invention in comparison to predicted values;

FIG. 7 is a schematic cross-sectional view of a thermistor in contact with a well in accordance with another embodiment of the invention;

FIGS. 8-10 are graphs illustrating the effect of various environmental media on temperature measurement sensitivity;

FIG. 11 is a graph illustrating exemplary temperature measurements as a function of time of a wellplate and sensor configuration in comparison to predicted values in accordance with one embodiment of the invention;

FIG. 12 is a schematic cross-sectional view of a plurality of wells in contact with a plurality of thermopiles in accordance with another embodiment of the invention;

FIG. 13 is a block diagram of an automated system in accordance with an embodiment of the invention; and

FIG. 14 is a schematic side view of a portion of an automated system in accordance with the block diagram of FIG. 13 in accordance with one embodiment of the invention.

### DETAILED DESCRIPTION

High throughput, non-contact optical infrared-based temperature measurement systems are under development by Thermogenic Imaging, Billerica, Mass., the assignee of the instant patent application. See, for example, U.S. Ser. No. 09/764,963, U.S. Ser. No. 09/777,363, U.S. Ser. No. 09/777,368, U.S. Ser. No. 09/777,364, and U.S. Ser. No. 10/001,892, all of which are incorporated herein by reference in their entirety.

In accordance with various embodiments of the instant invention, a sensor such as a thermistor or a thermopile contacts an external surface of a well in a disposable microtiter wellplate to measure temperature or heat flow, thereby eliminating the need for direct sensor contact with an assay inside the well or reuse of a dedicated instrumented sample container. In one embodiment, the mating surface of both the well and sensor may be contoured to promote thermal conduction and to isolate the sensor from contact with a surrounding medium,

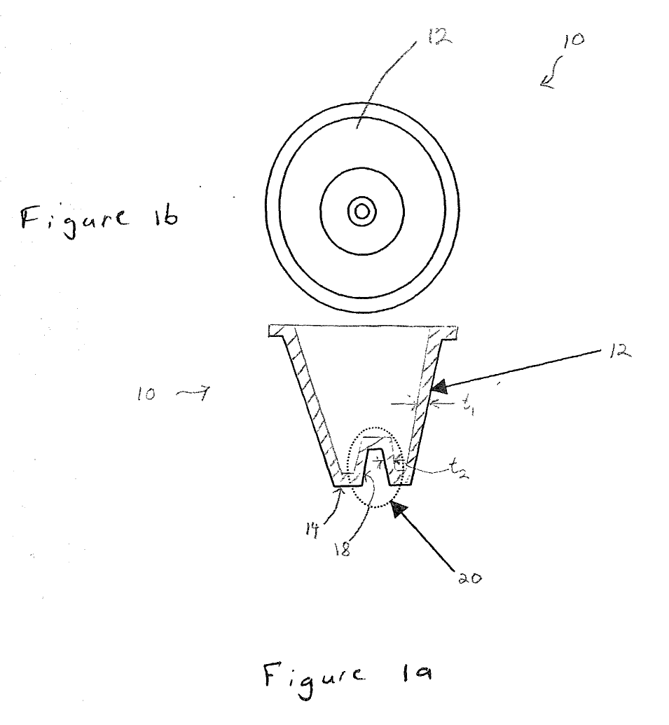

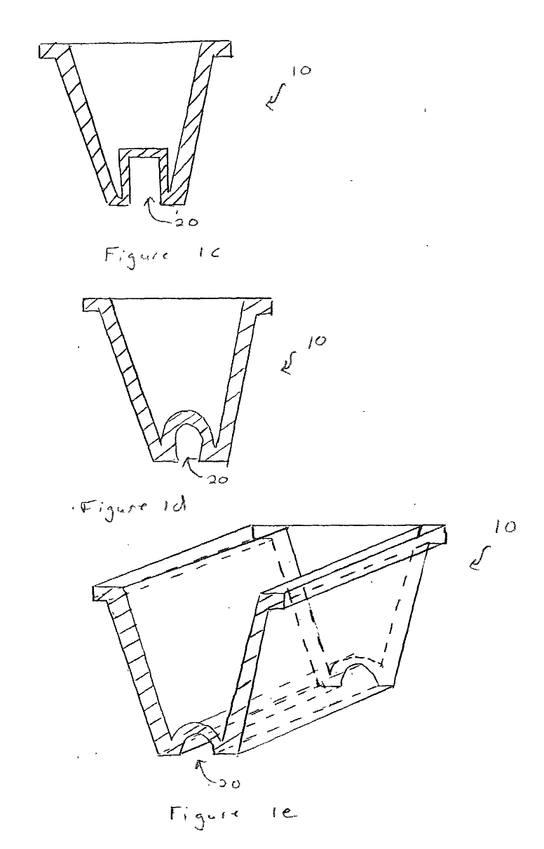

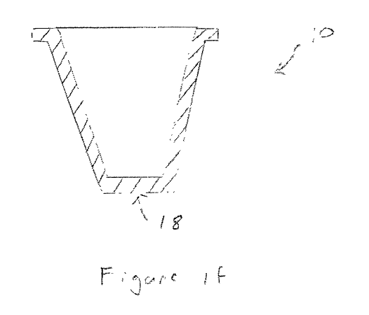

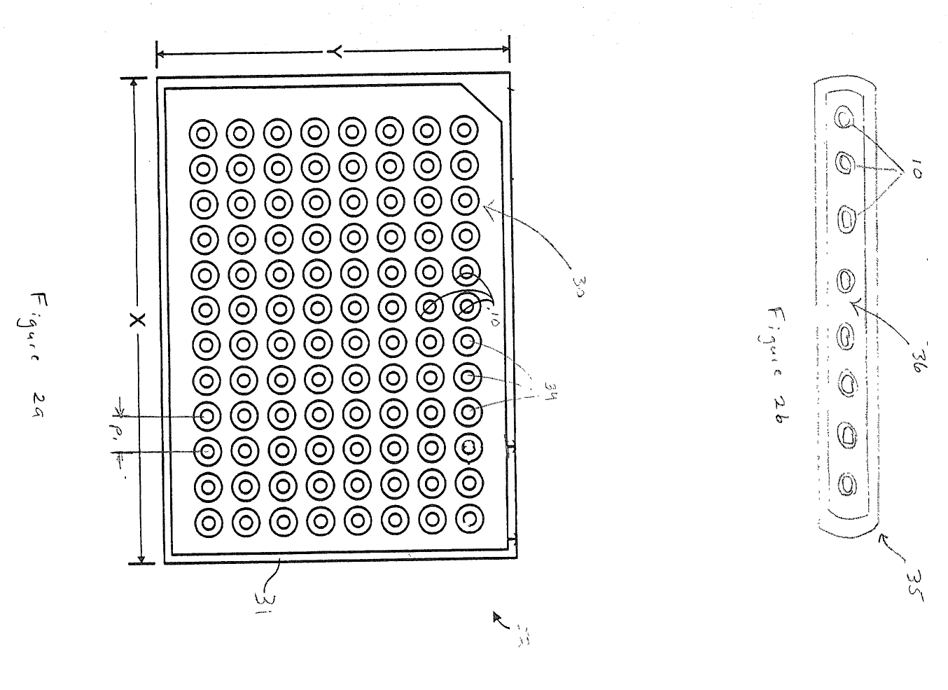

Referring to FIGS. 1a and 1b, a well 10 for use in microcalorimetry may vary in size and shape. Exemplary sizes are appropriate for holding volumes of material ranging from about 1 microliter (μl) to about 500 μl, preferably between about 1 μl to about 350 μl, and more preferably between about 1 μl to about 200 μl. As used herein and unless otherwise indicated, value, ranges of values, materials, and the like are exemplary in nature. Equivalents, alternatives, and deviations therefrom as would be apparent to those skilled in the art depending on a particular application are contemplated and considered to be within the scope of the disclosed invention. Exemplary well shapes include cones, frustums of cones, cylinders, and parallelepipeds, among others. In one embodiment, the well 10 has a sidewall 12 and an end wall such as a top wall of a cover or, in this case, a bottom wall 14, that define a frusto-conical shape. The sidewall 12 may be relatively thin, having a thickness t₁ of, for example, about 0.10 inches or less, preferably about 0.05 inches or less, more preferably about 0.010 inches or less. The well 10 may be made of a material that has a low thermal conductivity, e.g., less than 1.0 Watts/milliK (W/mK), preferably less than 0.6W/mK, more preferably less than 0.3 W/mK, to prevent the escape of heat generated by a reaction within the well 10.

The well 10 may be made of a material that supports cell adhesion and/or growth. An appropriate material may be, for example, a polymer such as polystyrene, polyethylene, e.g., ultra-high molecular weight polyethylene (UHMW-PE), polycarbonate, polypropylene, and acrylic, dimensioned and configured to be compliant to mate intimately with a sensor, as discussed in more detail hereinbelow. In some embodiments, a coating 16 may be formed on an inner surface of well 10. The coating 16 may include a material that supports cell adhesion and/or growth. An appropriate coating material may be, for example, polylysine, a collagen material, or a basement membrane protein.

Referring to FIGS. 1a-1f, the well 10 may be generally of a frusto-conical or channel shape, having a bottom wall 14 that has an exterior mating surface 18. Exterior mating surface 18 may be contoured, and it may define a depression 20 or other feature, such as a bulge, extension, protrusion, etc. The depression 20 may have a generally inverted frusto-conical shape relative to that of the well 10. Alternatively, depression 20 may be bullet-shaped, cylindrical, cone-shaped, or another shape. The mating surface 18 is adapted to mate with a sensor, such as a thermistor probe (see, e.g., FIG. 5a), generally with a slight interference fit to ensure intimate contact. In various embodiments, the depression 20 may be semi-circular (see, e.g., FIG. 1c) to accommodate a disk-shaped thermistor (see, e.g., FIG. 3b), semi-ellipsoidal or bead-shaped (see, e.g., FIG. 1d) to accommodate a bead-shaped thermistor (see, e.g., FIG. 3c), or semi-cylindrical or rod-shaped (see, e.g., FIG. 1e) to accommodate a rod-shaped thermistor (see, e.g., FIG. 3d). In some embodiments, the mating surface 18 may be flat (see, e.g., FIG. 1f) to accommodate a flat thermistor (see, e.g., FIG. 3e) or a thermistor embedded within flat slug 55 (see, e.g., FIG. 5b). The particular configuration of the mating surface 18 is selected depending on the configuration of the sensor. The portion of bottom wall 14 defining the mating surface 18 may be relatively thin, having a thickness t₂ of, for example, about 0.10 inches or less, preferably about 0.05 inches or less, more preferably about 0.010 inches or less. The thinness and high thermal conductivity of the mating surface 18 relative to the rest of the well 10 facilitate heat transfer from a sample inside well 10 to a sensor at least partially inserted into the depression 20 (see, e.g., FIG. 5). The portion of bottom wall 14 defining the mating surface 18 may compliant and able to adapt to a surface of a mating sensor. In other embodiments, the depression 20 may be defined by a mating surface of sidewall 12, instead of the end or bottom wall 14. In some embodiments, the mating surface of sidewall 12 may be flat. Generally, the portion of the well 10 adapted to mate with the sensor should be relatively thin with respect to the rest of the well 10. Alternatively or additionally, this portion of the well 10 should have a relatively low thermal resistivity to facilitate thermal transfer and measurement at this location of the well 10. The objectives can be met by geometry, material selection, or a combination of both. The well 10 could be made from two or more materials, as well.

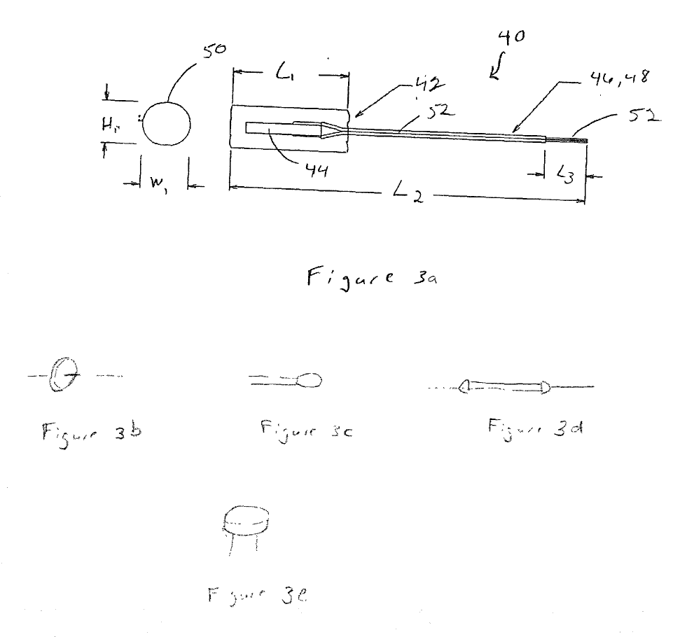

Referring to FIG. 2a, a plurality of wells 10 may be arranged as an array 30 of wells 10, disposed in a base plate 31 forming at least a portion of a wellplate 32. The wellplate 32 may also include a cover plate, as described further hereinbelow. The wellplate 32 may include various numbers of wells 10, such as 24, 96, 384, 864, 1536, 3456, and 9600 wells, among others. The wells 10 may be arranged in rectangular or hexagonal arrays, as well as other configurations. Three well configurations that will fit within a rectangular array in a microtiter wellplate are as follows:

| Number of | Arrangement | Pitch (mm) | Density (/mm²) |
|---|---|---|---|
| wells | of wells | between wells | of wells |
| 96 | 8 × 12 | 9 | 1/81 |
| 384 | 15 × 24 | 4.5 | 4/81 |
| 1536 | 32 × 48 | 2.25 | 16/81 |

Pitch, p₁, is the center-to-center well-to-well spacing, and density is the number of wells per unit area. One wellplate configuration includes 96 frusto-conical wells organized in an 8×12 rectangular array. The wellplate 32 may have an average width X of about 80 millimeters (mm) and an average length Y of about 120 mm. The wellplate 32 may be a disposable single-use component, thereby eliminating the need for cleaning the wellplate, as well as preventing contamination of assays due to incomplete cleaning and sterilization. As illustrated, each well 10 contains a material 34, i.e., an assay. The material 34 may be any chemical or biological assay whose thermal characteristics are sought to be determined.

Referring to FIG. 2b, in some embodiments, a plurality of wells 10 may be arranged in a wellplate 35 as a strip 36 of wells 10. The strip 36 of wells 10 may include various numbers of wells 10, such as 8, 12, 16, and 24 wells, among others.

Referring to FIG. 3a, a sensor 40 may be a thermistor assembly, including a thermistor 42, i.e., a thermally sensitive resistor. The thermistor 42 may be a negative temperature coefficient (NTC) thermistor, whereby a resistance of the thermistor 42 is inversely proportional to a temperature sensed by the thermistor 42. The thermistor 42 may include a semiconductor material, such as, for example, a metallic oxide of any of a variety of metals, e.g., manganese, nickel, cobalt, copper, iron, and titanium, shaped in one of several configurations, such a disk (see, e.g., FIG. 3b), a bead (see, e.g., FIG. 3c), a rod (see, e.g., FIG. 3d), or another shape. The thermistor 42 may have a bore filled with epoxy 44. The thermistor 42 may be coated with a protective glass or other layer and may be connected to electrical leads, such as two bifilar leads 46, 48, i.e., two wires wound side by side. Bifilar leads 46, 48 may include a conductive material such as tinned copper. The thermistor 42 may have a length L₁ ranging between, e.g., about 0.080 inches-0.100 inches and a cross-section 50 with a height H₁ of, e.g., about a maximum of 0.0185 inches and a width W₁ of, e.g., about a maximum of 0.0185 inches. The cross-section 50 may be generally circular. The total length L₂ of thermistor 42 and bifilar leads 46, 48 may be, e.g., 0.072±0.001 inches. Each of leads 46, 48 may have a relatively small size of, e.g., 38 American Wire Gauge (AWG) corresponding to a diameter of 0.004 inches. An insulation 52 surrounding each of leads 46, 48 may be stripped off an end of each of leads 46, 48 distal to thermistor 42, and a portion 52 of leads 46, 48 may be exposed. Exposed portions 52 of the leads 46, 48 may have a length L₃ sufficient for connection to a meter or circuit, e.g., approximately 0.13±0.06 inches. Thermistor 42 may have a low mass and a high resistance, such as, for example, an STD9 thermistor, e.g., model PN H349MMM223TM, available from Sensor Scientific, Inc., Fairfield, N.J. Selection of the thermistor 42 may be based on configuration and operating criteria, such as high signal gain, low self-heating, and rapid response.

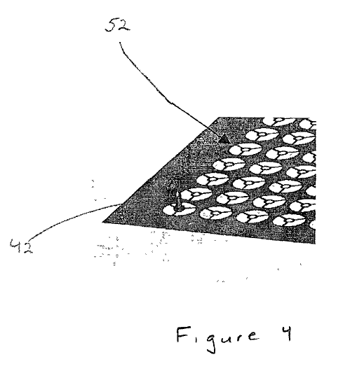

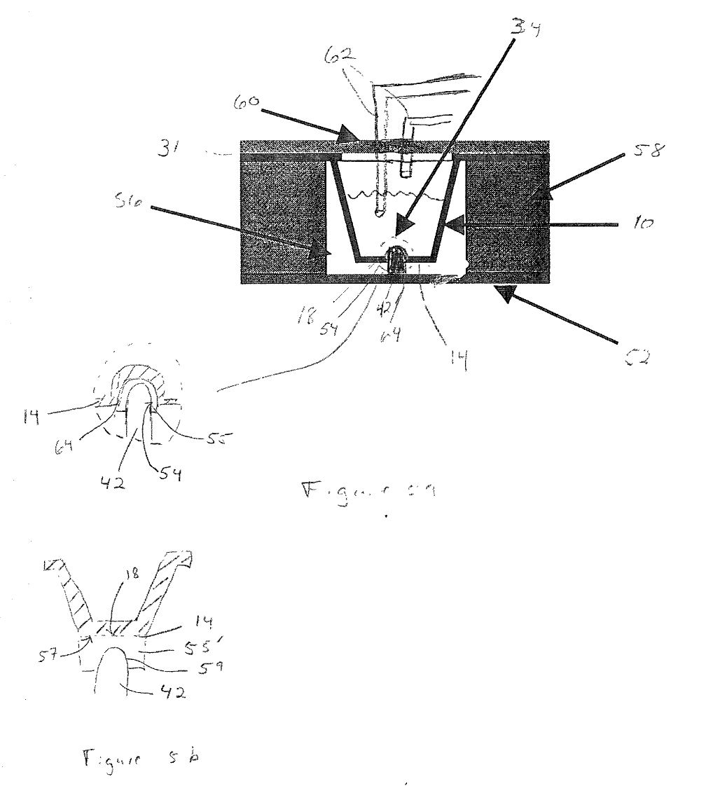

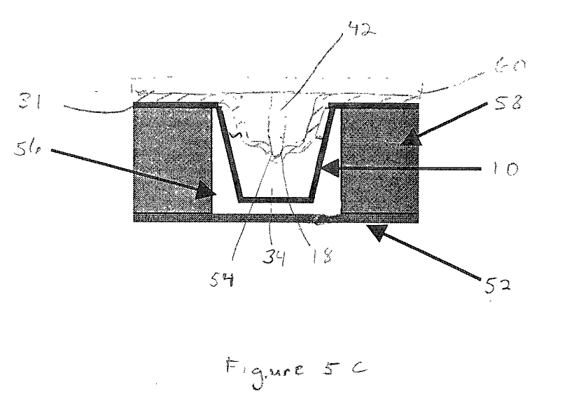

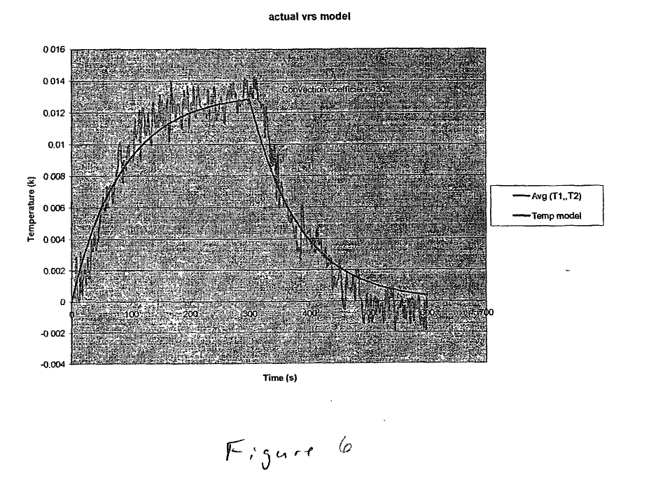

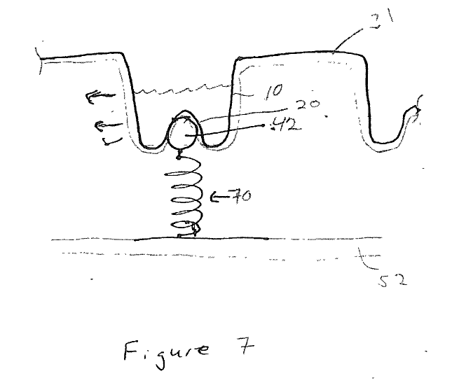

Referring to FIG. 4, thermistor 42 may be bonded or otherwise attached to a base 52. The base 52 provides thermal isolation of the thermistor 42 by providing high thermal resistance and may advantageously have a low mass. The base 52 may be formed from micro-etched stainless steel or other suitable material. An array of thermistors 42 may be arranged on the base 52 in a configuration corresponding to the arrangement of wells 10 in the wellplate 32, more specifically the arrangement of mating surfaces 18 or depressions 20 in the wellplate 32. Leads 46, 48 from each of thermistor 42 may be connected to a multiplexer with a precision 6.5 digit multimeter, such as an Agilent 34970A data acquisition switch unit, available from Agilent, Palo Alto, Calif. This arrangement allows each thermistor 42 to be biased by a precision current source for a controlled period to avoid self-heating, and to be measured through a multiplexed output with solid state switches. Leads 46, 48 may be multiple microwires that transmit to a microprocessor data that is indicative of data that is being captured

In use, measured resistance data may be transferred to computer memory and processed using a Steinhart-Hart equation:

1/T=A+B(1n R)+C(1nR)³ Equation 1

where

T is expressed in degrees Kelvin,

R is resistance at temperature T, and

A, B, C are derived equation constants.

A temperature value as a function of time may thus be computed for each thermistor 42 in the array on base 52, corresponding to reactions in each well 10 in the wellplate 32.

Referring to FIG. 5a, the thermistor 42 has a complementary surface 54 for mating with at least a portion of the mating surface 18 of the well 10. The complementary mating surface 54 may be disposed, optionally, on a conductive slug 55 attached to the thermistor 42. The conductive slug 55 may be formed from a thermally conductive material, such as aluminum (thermal conductivity=204 W/mK). In use, the thermistor 42 is mounted on the base 52 and is placed in contact with the bottom wall 14 of the well 10, so that thermistor complementary mating surface 54 mates with at least a portion of the mating surface 18 of the well 10. The well 10 contains a material 34, e.g., an assay, whose temperature is measured by the thermistor 42. To accurately measure the material temperature, it is generally desirable to thermally isolate the well 10 from the other wells, such as proximate wells, and from ambient conditions, for example by using dead air insulation 56, vacuum beads, or a vacuum to surround the well 10, as well as a thermal isolator 58 having a high thermal mass. The thermal isolator 58 may be formed from a material having a high thermal mass (heat capacity) and high thermal conductivity, such as aluminum and/or other metals. Materials such as aluminum may reduce the time required for thermal stabilization within the test chamber. In particular, a high thermal mass thermal isolator 58 may function as a thermal buffer, helping to maintain a constant temperature around the well 10. A cover plate 60 may be positioned over the well 10 to prevent evaporation of the material 34. The cover plate 60 may be a generally planar film layer or a complexly contoured molded or formed plate, similar to the base plate 31. In some embodiments, the cover plate 60 or the base plate 31 of the wellplate 32 may include one or more embedded perfusion channels 62 or conduits in fluidic communication with the well 10 for delivering material 34 to or from the well 10. In some embodiments, the perfusion channel 62 may be used to keep cells in the well 10 alive by providing nutrients or a sustaining environment, e.g., oxygen supply. In some embodiments, a thermally-conductive medium 64 may be placed proximate the contact between the sensor 42 and the well 12 to reduce thermal resistance between the sensor 42 and the well 10. The thermally-conductive medium 64 may be, for example, thermal grease, such as aluminum thermal grease or silver filled thermal grease.

Referring to FIG. 5b, in an alternative embodiment, the mating surface 18 of the bottom wall 14 of well 10 is flat. Optionally, a slug 55′ attached to or encapsulating the thermistor 42 has a flat contoured portion 57 adapted to mate with the flat mating surface 18 and a contoured portion 59 adapted to receive thermistor 42.

Referring to FIG. 5c, in an alternative embodiment, the cover plate 60 of the wellplate 32 defines the mating surface 18. The thermistor 42 has a complementary surface 54 for mating with at least a portion of the mating surface 18 of the cover plate 60. In this embodiment, the mating surface 18 is submerged in the assay material 34.

In general, the well 10 has a low thermal mass, with bottom wall 14, sidewall 16, and, optionally, a top wall formed by the cover plate 60 having relatively low thermal conductivity to reduce conduction and other heat transfer mechanisms to thermal ground. The mating surface 18 is configured to increase locally the thermal contact area between the thermistor 42 and a reaction within the well 10, and to reduce exposure to surrounding ambient. In certain embodiments, the mating surface 18 may be preferentially thin and/or exhibit a lower thermal resistance and higher thermal conductivity than the rest of the well 10.

The thermodynamic properties of the well 10 may be described as follows. For a given energy input, with known material volume, the resulting temperature rise may be modeled as a function of heat loss. For a reaction with a constant input, a steady state condition exists when heat entering the system (qᵢₙ) is equal to heat flowing out of the system (qₒᵤₜ), i.e., qᵢₙ=qₒᵤₜ. Heat transfer is equal to the sum of the heat of conduction, the heat of convection, and the heat of radiation:

qᵢₙ=qₒᵤₜ=Σ(q_{conduction}+q_{convection}+q_{radiation}) Equation 2

When a system including the well 10 and the material 34 is at steady state, qᵢₙ may be determined by measuring the temperature of the material 34 and determining the steady state heat loss, qₒᵤₜ. To further understand the thermodynamic heat loss (qₒᵤₜ), a model may be constructed to mathematically simulate assay conditions. The model takes into account the geometric constraints on the thermal isolator 58 (air gaps and conduction paths), materials, fluid volumes, and fluid type. Because the air volume 56 surrounding the well 10 is relatively small, and the air volume is trapped to eliminate air flow, the convection component may be treated as a conduction path through air. While the thernistor 42 may be considered a conductive path, the effect is generally negligible and can be ignored in the model. Hence, based on the geometry illustrated in FIG. 5a, qₒᵤₜ has three primary paths:

1. a conduction path through the well 10 to the thermal isolator 58:

q_{conduction}=K_{cup}*A/L*(T−Tₐ)_{well}

2. a conduction path from the well 10, through the air, to the thermal isolator 58:

q_{convection}=Kₐᵢᵣ*A/L*(T−Tₐ)ₐᵢᵣ

3. radiation loss from the well 10, through the air, to the thermal isolator 58:

q_{radiation}=e*C*A*(T⁴−Ta⁴)

where

Q=energy (Joules)

q=heat flow rate (watts)

K=conduction coefficient (W/M ° K.)

A=area (M²)

L=path length (M)

T=temperature of the well media (Kelvin)

Tₐ=temperature of the ambient (Kelvin)

e=emissivity

C=Stefan Boltzmann constant

q=heat flow rate (Watts)

t=time (seconds)

By combining q_{conduction}, q_{convection}, and q_{radiation}, one obtains the following formulation of q_{out:}

qₒᵤₜ=Kₐᵢᵣ(A/L)(T−Tₐ)_{cup}+K_{well}(A/L)(T−Tₐ)ₐᵢᵣ+eCA(T⁴−Tₐ⁴) Equation 3

Referring to FIG. 6, by using Equations 2-3, and knowing the heat capacity (thermal mass) of the sample, a model may be constructed that, based on a constant input power and time, will return a net rise in temperature. Conversely, if the input power is shut off, the temperature differential will decay to zero over a defined period of time. This decay curve describes the actual thermodynamic properties of the wellplate 32 and may be used to determine the heat flow of a reaction. Equation 4 describes the relationship between heat flow qᵢₙ, sample temperature change (dT), sample mass, and time:

dT=(qin*t)/(Cₚ*m) Equation 4

where

Cₚ=specific heat (Joules/kg*K)

m=mass (kg)

Referring to FIG. 7, in one embodiment, the sensor 40 is disposed between a mating surface 18 of the well 10 and a component 70 having a high thermal resistance, such as the base 52 depicted in FIG. 4. The component 70 may thermally isolate the sensor 40, such as thermistor 42, from thermal ground. This configuration is semi-adiabatic, i.e., the transfer of heat from the well 10 to the surroundings is minimized. The heat created by an assay in the well 10 is calculated based on temperature rise, as determined by the thermistor 42. The reaction is thermally contained in the well 10, and the temperature may be measured by the thermistor 42 disposed in contact with the thin wall material which forms the depression 20. The high thermal resistance component 70 may also be used, advantageously, to mechanically bias the thermistor 42 into intimate contact with the wall forming the depression 20. See, for example, the three radial arms supporting the thermistor 42 in FIG. 4.

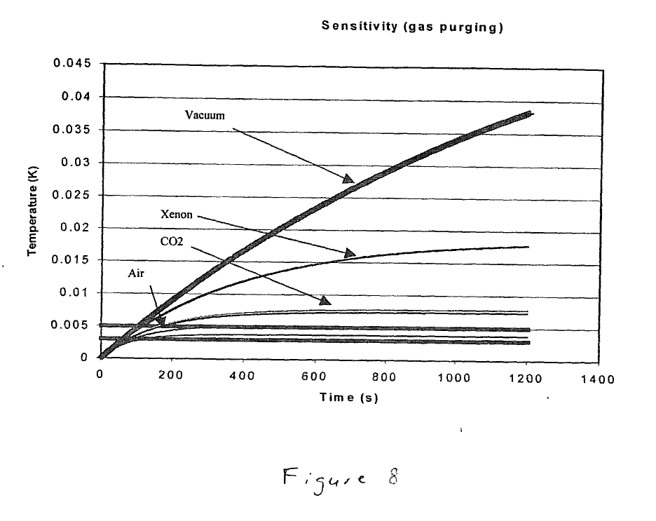

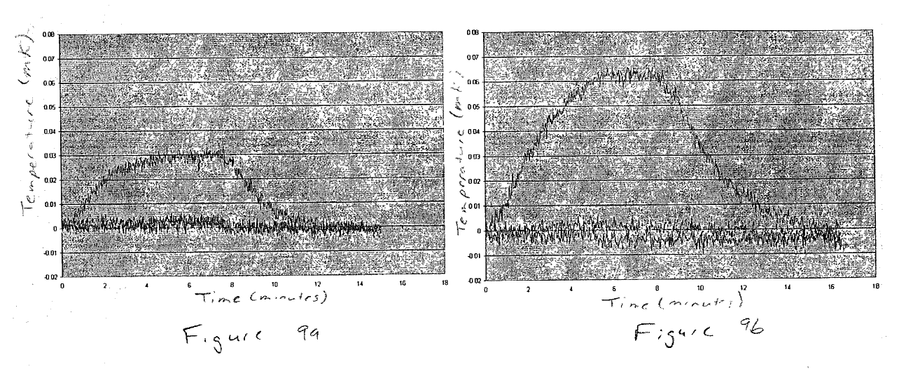

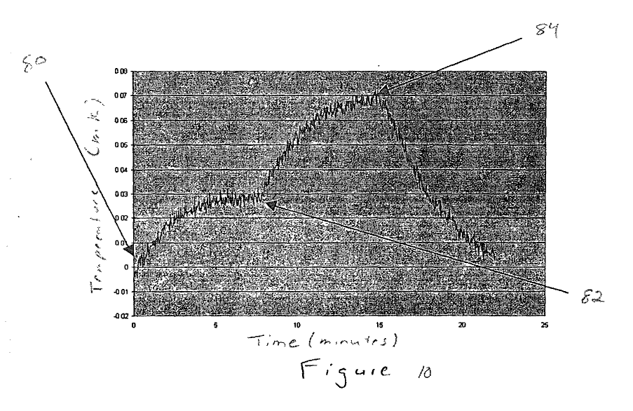

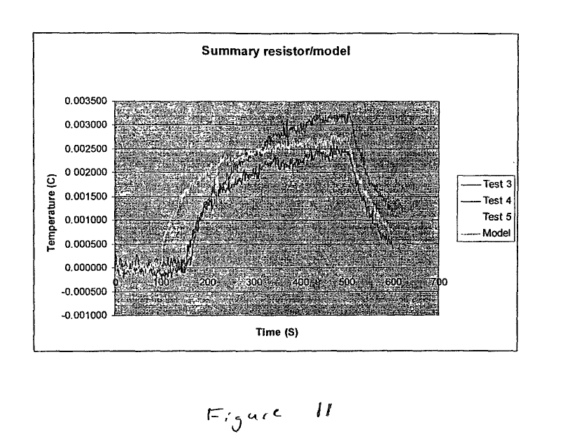

Referring to FIGS. 5a and 8, temperature measurement sensitivity of the thermistor 42 may be improved by controlling composition of the gas disposed in the dead air space 56. The conduction properties of the gas surrounding the well 10 can affect the accuracy of measurements made by the thermistor 42. For example, providing a vacuum by completely evacuating the dead air space 56 allows one to carry out reactions in a virtual Dewar flask with significant improvement in signal, because the bulk of signal loss (through gas to ground) is eliminated. Alternatively, air may be substituted with a gas having lower thermal conductivity to amplify the signal obtained by the thermistor 42. FIG. 8 illustrates the predicted rise in signal for a constant 30 microwatt input, when dead air space 56 is purged with various gases, including vacuum, xenon, carbon dioxide, and air.

The specified thermal conductivity values for the various gases are as follows:

| | Thermal conductivity |
|---|---|
| Gas | (W/m° K) |
| Air | 0.026 |
| CO₂ | 0.017 |
| Argon | 0.018 |
| Vacuum | 0.0 |
| Xenon | 0.0057 |

As illustrated in FIG. 8, with a constant 30 μWatt input, the signal in air reaches about 6 mK while the same input reaches 17 mK when the system is purged with a xenon gas, i.e., xenon gas amplifies the signal more than twice the value attained with air.

Referring to FIGS. 9a and 9b, the model was verified with a series of experiments in which a system was purged with a gas while thermal data was simultaneously measured at the bottom of the wellplate and recorded. An electro-optic emitter provided a small energy input to one of 96 wells, and the remaining wells were used as a control. As seen in FIG. 9a, in a control experiment, the system was purged with air. A constant input of 150 μWatt resulted in a 30 mK signal from the wellplate. At the top of the signal curve, about eight minutes after the start of the test, the emitter was turned off and the signal allowed to decay back to the control value. Referring to FIG. 9b, the same signal input (150 μWatt) was applied in conjunction with flooding the wellplate with a xenon gas purge. Here, the resulting signal increased to 62 mK, more than double the signal attained with an air purge.

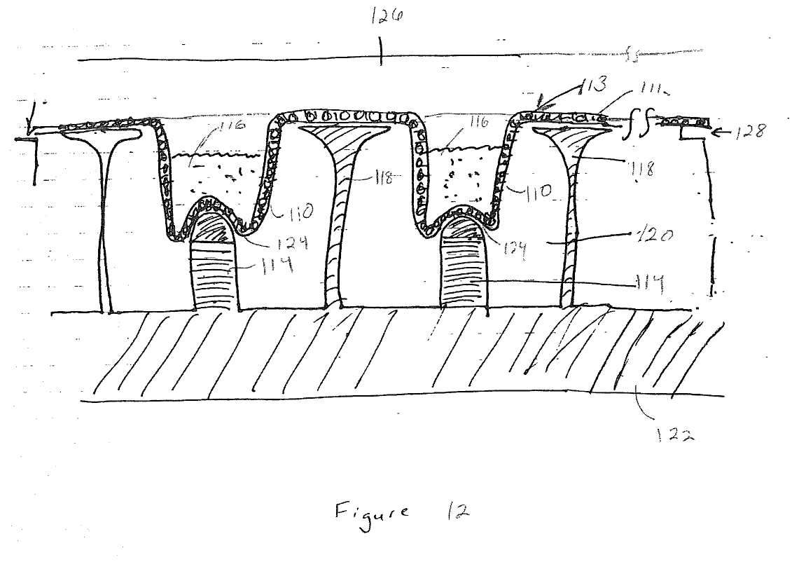

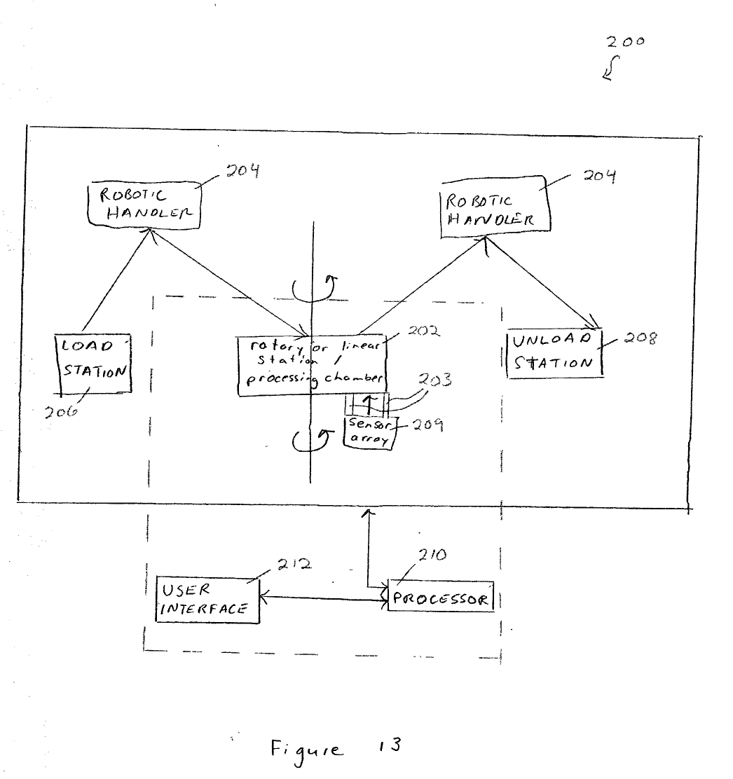

Referring to FIG. 10, a second series of tests were conducted. Here, the input emitter was turned on at point 80 with about 150 μWatts of input power, while the wellplate was flooded with air. As expected, the signal as measured by a detector increased over time to a point 82 where the rate of heat flow into the well was equal to the heat flow out, and hence a steady state condition existed with the temperature remaining constant. At that point 82, about eight minutes into the test, the wellplate was flooded with xenon gas at a rate of about 1 liter/minute to remove the air and to reduce conduction between the thermal isolator and the well. The signal increased as heat flow was reduced with air being replaced by xenon. The signal increased by a factor of more than two over a period of five minutes after the gas was turned on. The signal decayed after the input power was turned off at point 84. Referring to FIG. 11, the configuration described above (see, e.g., FIG. 5a) enables the measurement of, for example, a 2.5 mK reaction, with less than 0.5 mK of noise.

In an alternative configuration depicted in FIG. 12, a plurality of wells 110 formed in a baseplate 111 of a wellplate 113 and a plurality of sensors 114 are arranged to enable the measurement of thermal flow from assays 116 contained in wells 110 through the sensors 114 to a thermal ground, such as a heat sink 122. Here, the sensors 114 may be thermopiles, i.e., thermal-sensing voltage-generating devices that each include a plurality of thermocouples connected in series. Commercially available thermopiles 114 that can be used in accordance with the teachings of the invention may be obtained from, e.g., Ferrotec in Nashua, N.H.

A plurality of thermal isolators 118 is placed between individual wells 110 to isolate the heats of reaction of individual assays 116. A space 120 between the wells 110, sensors 114, and thermal isolators 118 may be at least partially evacuated. In this condition, contact between each well 110 and sensor 114 is improved by the evacuation of the space 120, insofar as each well 110 is biased against the proximate sensor 114. The sensors 114 and thermal isolators 118 can be attached to the heat sink 122, with at least a portion of each sensor 114 contacting the heat sink 122. A generally compliant bottom portion 124 of each well 110 is in contact with a portion of each sensor 114. The bottom portion 124 of each well 110 may be relatively thin, e.g., about 0.10 inches or less, preferably about 0.05 inches or less, more preferably about 0.010 inches or less, to enhance heat sensing by each sensor 114. A cover plate 126 or film layer can be placed over the wells 116 to prevent evaporation and to further thermally isolate the assays 116 from the environment. In some embodiments, the wellplate 113 may be biased against the sensors 114, e.g., mechanically, pneumatically, hydraulically, magnetically, etc., to ensure intimate contact between each well 110 and sensor 114. The wellplate 113 may be biased against the sensors 114 by a pressure differential. Additionally, wellplate 113 can include a seal 128 disposed at an outer perimeter to enable the evacuation of space 120 surrounding each well 110. As with the thermistor configuration depicted in FIG. 5c, the sensor arrangement can be inverted, so that the thermopiles 114 sense the temperatures in the wells 110 through the cover plate 126.

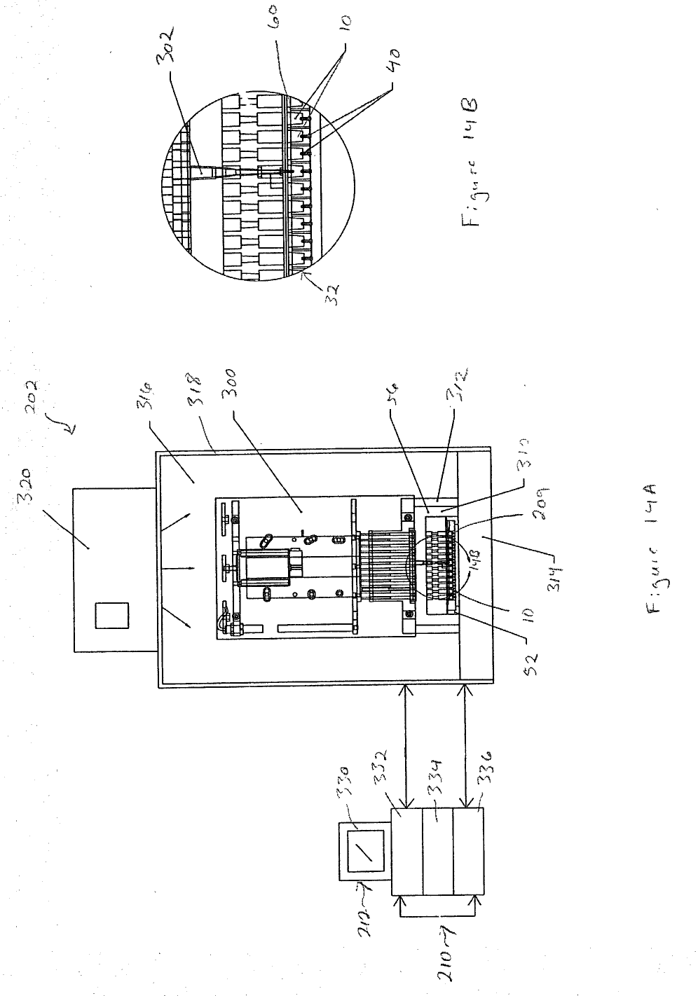

Referring to FIG. 13, the temperature-sensing configurations described above may be incorporated into an automated system 200 to achieve the benefits associated therewith, such as high throughput and efficiency. The automated system 200 includes a processing chamber 202 optionally integrated with a rotary station or a linear translation station. A registration structure 203, such as an elevator, cooperates with the processing chamber station to position and mate the wellplate 32 and a plurality of sensors, such as a sensor array 209, in the processing chamber 202. Suitable alignment guides, travel limiters, proximity switches and the like may be provided to ensure accurate, repeatable registration of the wellplate 32 and sensor array 209, as are known to those skilled in the art of automated processing equipment. The wellplate 32 (see FIG. 2) can be transported to and from the processing chamber 202 by a handling system 204, such as a robotic handler. Two separate robotic handlers 204 may be used, one for delivery of the wellplate 32 to and one for removal of the wellplate 32 from the processing chamber 202. Alternatively, a single robotic handler 204 may be used for both delivery and removal of the wellplate 32 or the wellplate 32 can be handled manually. Automated system 200 may include a load station 206 and an unload station 208 for holding a plurality of wellplates 32 before and after processing in the process chamber 202, respectively. In some embodiments, the load station 206 and the unload station 208 may be a single portal.

The sensor array 209, such as an array of thermistors 42 (see FIG. 4), is arranged to mate with the wells 10 of the wellplate 32 in the processing chamber 202. The movement of the rotary or linear station, as well as the handling system 204, may be controlled by a processor 210. The processor 210 may be, for example, a personal computer. The processor 210 may also receive signals from the sensor array 209, indicating the temperatures of reactions that take place in the wellplate 32 in the processing chamber 202. An operator may use a user interface 212 to control the overall system 200, as well as discrete components such as the robotic handler 204 and the components disposed in the processing chamber 202 by sending commands to the processor 210. The user interface 212 typically includes input devices such as a keyboard or a touch screen, as well as output devices, such as a display or a printer. Depending upon the duration of reactions to be monitored, the system 200 may process up to four or more wellplates per hour, with processing of a single wellplate requiring a cycle time of about 15 minutes to one hour. Multiple wellplate stations may be provided in the processing chamber 202, under environmental control, to permit temperature equilibration, prior to initiating and measuring the temperature of reactions in the wells. The system 200 of the invention may use handling and controlling technology similar to that incorporated in optical IR non-contact temperature measurement systems, such as the TSA AnalyzIR, being developed by Thermogenic Imaging, Billerica, Mass.

Referring to FIG. 13 as well as FIGS. 14a and 14b, in one embodiment, processing chamber 202 includes an automated fluid delivery system 300 for delivery of liquids, such as samples or reagents, to the wells 10. The automated delivery system 300 includes an array of pipettes 302 for delivering fluids through the cover plate 60 of the wellplate 32. The array 209 of sensors 40, attached to the base 52 is brought into intimate contact with the wells 10 within an inner environmental chamber 310 of the processing chamber 202. Dead air insulation 56 within the inner environmental chamber 310 or other techniques discussed hereinabove may be employed to thermally isolate the wells 10. An environmental barrier 312, such as, e.g., the thermal insulator 58 encloses the inner environmental chamber 310 and contains the dead air insulation 56. The environmental barrier 312 is attached to a block 314 made of a material having a high thermal mass and high thermal conductivity, such as aluminum and/or other metals. An outer environmental chamber 316, enclosed in a system housing 318, provides additional environmental control, including thermal isolation for wells 10 and sensors 40. An environmental control unit 320 mounted on the housing 318 controls the environment, e.g., temperature, air flow, etc., within the inner 310 and outer 316 environmental chambers. The user interface 212 includes a monitor 330. The processor 210 includes a data acquisition and processing unit 332, a multimeter 334, and a multiplexer 336. The processor 210 is in communication with the sensor array 209 and is configured to receive signals indicative of temperature changes in the wells 10.

Different sensing mechanisms may be used in various embodiments of the invention, as long as the sensing mechanism is capable of detecting the small temperature changes resulting from the reactions. The sensing mechanism may include, for example, a thermistor for measuring a reaction in thermal isolation or a thermopile for measuring thermal conduction to ground. The construction of the system, e.g., wellplates, is adapted to the sensing mechanism employed to enable accurate, quick measurements of very small temperature changes with high throughput. This capability is provided by using the specialized wells and wellplates described herein.

The inventors have previously disclosed a multi-channel calorimetric system embodying a removable wellplate and a thermal imaging (infrared) sensor. This system demonstrated heat flow sensitivity of approximately 50 microwatts when used with samples contained within the wells of a 96 well microtiter plate. The well/sensor configurations of various embodiments of this invention are capable of providing enhanced measurement capabilities heretofore unknown in automated non-contact systems using disposable media. Typical operating capabilities are contemplated to be on the order of a magnitude better than IR systems, including heat flow sensitivity of approximately five microwatts or less.

To achieve the maximum benefits of a high throughput, efficient, automated system in accordance with one embodiment of the invention, the wellplates may be disposable or deemed single-use due to low cost and/or physical characteristics. For example, the wellplate may be physically degraded so that it cannot be used effectively a second time, or it may not be capable of being adequately rejuvenated, repaired, or refurbished to a useable condition. Depending on the configuration of the wellplate and the material from which the wellplate is made, the wellplate may be unable to withstand the high temperatures or other conditions that may be needed for thorough cleaning and sterilization.

While specific examples of sensors have been discussed, such as thermopiles and thermistors, various other sensors may be used in accordance with the invention. Such sensors may be contact temperature sensors such as thermometers, thermo-electrical sensors such as RTDs, and PRTs, or thermo-mechanical sensors whose properties are monitored by capacitance or resistance sensors. Other sensors include wafer scale or chip level sensors, such as p-n junction semiconductor devices with suitable signal amplification, including a p-n diode, an n-type transistor or a p-type transistor.

The invention may be embodied in other specific forms without departing from the spirit or essential characteristics thereof. The foregoing embodiments are therefore to be considered in all respects illustrative of the invention described herein. Various features and elements of the different embodiments can be used in different combinations and permutations, as will be apparent to those skilled in the art. Scope of the invention is thus indicated by the appended claims rather than by the foregoing description, and all changes which come within the meaning and range of equivalency of the claims are therefore intended to be embraced herein.

We claim:

1. A wellplate comprising:
a plurality of wells, each well including a sidewall and an end wall adapted to receive a material therein,
wherein at least one of the sidewall and the end wall of at least one well comprises a mating exterior surface adapted to mate with a thermal sensor, thereby enabling precise thermal measurement of a sample contained in the well, and the plurality of wells is adapted to mate with a plurality of thermal sensors.

2. The wellplate of claim 1 wherein the mating surface of the at least one well comprises a contoured surface.

3. The wellplate of claim 2 wherein the mating surface comprises a depression.

4. The wellplate of claim 3 wherein the depression is substantially uniform about an axis of rotation extending through the depression.

5. The wellplate of claim 1 wherein the mating surface is compliant and able to adapt to a surface of a mating sensor.

6. The wellplate of claim 1 wherein the wellplate is disposable.

7. The wellplate of claim 1 wherein the wellplate comprises a microtiter wellplate.

8. The wellplate of claim 1, further comprising:
a thermal isolator disposed proximate the at least one well, the thermal isolator adapted to thermally isolate the at least one well from a proximate well.

9. The wellplate of claim 8 wherein the thermal isolator is selected from the group consisting of air, xenon, argon, carbon dioxide, vacuum, vacuum beads, and combinations thereof.

10. The wellplate of claim 1 wherein the wellplate comprises a baseplate and a cover plate.

11. The wellplate of claim 10 wherein at least one of the baseplate and the cover plate forms at least one channel in fluidic communication with at least one well.

12. The wellplate of claim 1 wherein a thickness of the at least one of the sidewall and end wall having a mating surface is less than a thickness of a remainder of the at least one well.

13. The weliplate of claim 1 wherein a thermal conductivity of the at least one of the sidewall and end wall having a mating surface is greater than a thermal conductivity of a remainder of the at least one well.

14. The wellplate of claim 1 wherein an interior surface of the at least one well comprises a material supporting cell adhesion.

15. The wellplate of claim 14 wherein the at least one well comprises a polymer.

16. The wellplate of claim 1, further comprising:
a coating disposed on an inner surface of the at least one well, the coating comprising a material promoting cell adhesion.

17. The wellplate of claim 16 wherein the coating comprises at least one of polylysine, a collagen material, and a basement membrane protein.

18. The wellplate of claim 1 wherein the wellplate is substantially rectangular.

19. The wellplate of claim 1 wherein the plurality of wells comprises an array of wells.

20. The wellplate of claim 19 wherein the array of wells comprises a number of wells selected from the group consisting of 24, 96, 384, 768, 1536, 3456, and 9600.

21. The wellplate of claim 1 wherein a density of sample wells in the wellplate is at least about one well per 81 mm².

22. The wellplate of claim 1 wherein the plurality of wells comprises a strip of wells.

23. The wellplate of claim 22 wherein the strip of wells comprises a number of wells selected from the group consisting of 8, 12, 16, and 24.

24. The wellplate of claim 1 wherein a volume of each well is less than about 500 microliters.

25. An apparatus for monitoring a temperature of a material, the apparatus comprising:
a wellplate comprising a plurality of wells for containing the material, at least one well having a compliant mating surface; and
at least one sensor having a complementary surface for mating with at least a portion of the mating surface of the at least one well,
wherein the sensor is adapted to monitor the temperature of the material in the at least one well.

26. The apparatus of claim 25 wherein the at least one well is biased against the sensor by a pressure differential.

27. The apparatus of claim 25 wherein the at least one sensor is selected from the group consisting of a thermistor, a platinum resistance thermometer (PRT), a resistance temperature detector (RTD), a diode, and a transistor.

28. The apparatus of claim 25, further comprising:
at least one component having a high thermal resistance,
wherein the at least one sensor is disposed between the mating surface and the at least one component, and the at least one component thermally isolates the at least one sensor from thermal ground.

29. The apparatus of claim 25 wherein the at least one sensor comprises a thermopile.

30. The apparatus of claim 29, further comprising:
a heat sink,
wherein at least a portion of the at least one thermopile contacts the heat sink.

31. The apparatus of claim 25 wherein the mating surface of the at least one well comprises a depression.

32. The apparatus of claim 25 wherein the at least one well comprises a thin wall portion.

33. The apparatus of claim 32 wherein the thin wall portion has a thickness less than about 0.01 inches.

34. The apparatus of claim 25 wherein the at least one well comprises a material supporting cell adhesion.

35. The apparatus of claim 34 wherein the at least one well comprises a polymer.

36. The apparatus of claim 25, further comprising:
a coating disposed on an inner surface of the at least one well, the coating comprising a material promoting cell adhesion.

37. The apparatus of claim 36 wherein the coating comprises at least one of polylysine, a collagen material, and a basement membrane protein.

38. A method for monitoring a temperature of a material, the method comprising:
providing a well for containing the material, the well comprising an external mating surface;
placing the material into the well;
contacting at least a portion of the external mating surface of the well with a sensor having a complementary mating surface for mating with the mating surface of the well; and
determining the temperature of the material in the well based at least in part on an output of the sensor.

39. The method of claim 38 wherein the sensor is selected from the group consisting of a thermistor, a platinum resistance thermometer (PRT), a resistance temperature detector (RTD), a diode, and a transistor.

40. The method of claim 38 wherein the sensor comprises a thermopile attached at one end to a heat sink.

41. The method of claim 38, further comprising:
providing a medium proximate the contact between the sensor and the well for reducing thermal resistance between the sensor and the well.

42. The method of claim 41 wherein the medium comprises thermal grease.

43. The method of claim 42 wherein thermal grease is selected from the group consisting of aluminum thermal grease and silver filled thermal grease.

44. The method of claim 38, further comprising:
providing a medium proximate the sensor and the well for thermally isolating the sensor and the well from ambient.

45. The method of claim 44 wherein the medium is selected from the group consisting of air, xenon, argon, carbon dioxide, vacuum, vacuum beads, and combinations thereof.

46. A system for monitoring temperatures in a plurality of wells in a wellplate, each well including a sidewall and an end wall adapted to receive a material therein, at least one of the sidewall and the end wall comprising a mating exterior surface adapted to mate with a sensor, the system comprising:
a plurality of sensors adapted to mate with the mating exterior surfaces of the wells;
a processing chamber adapted to receive the wellplate and to position the sensors to mate with the mating exterior surfaces of the wells;
a handling system configured to transport the wellplate to and from the processing chamber; and
a processor configured to control movement of the wellplate and to receive signals from the sensors.

47. The system of claim 46 wherein the wellplate comprises an array of wells.

48. The system of claim 46, further comprising:
a loading station adapted to hold the wellplate prior to transport of the wellplate to the processing chamber.

49. The system of claim 46, further comprising:
an unloading station adapted to hold the wellplate subsequent to transport of the wellplate from the processing chamber.

50. The system of claim 46, further comprising:
a user interface connected to the processor.

51. An apparatus for detection of changes of temperature in each of a plurality of wells in a wellplate, the wells adapted for receiving test samples and comprising respective thermally conductive portions, the apparatus comprising:
a sensor array for sensing temperature, the sensor array including a base for supporting a plurality of sensors positionable in thermal communication with the wells; and
a registration structure for facilitating mating of the wellplate and the sensor array so as to register respective thermal sensors with respective wells of the wellplate, thereby to obtain data indicative of temperature changes in respective wells by detecting heat conducted through the thermally conductive portions.

52. The apparatus of claim 51, further comprising:
a thermal insulator disposed between the wells to minimize heat transfer from a well to a sensor registered with a different well.

53. The apparatus of claim 51, further comprising:
a thermal insulator disposed between the sensors to minimize heat conductance from a well to a sensor registered with a different well.

54. The apparatus of claim 51, further comprising:
a handling system configured for transporting the wellplate to and from the sensor array.

55. The apparatus of claim 51, further comprising:
an automated fluid delivery system for filling the wells in the wellplate.

56. The apparatus of claim 51, further comprising:
a processor in communication with the sensors, the processor configured to receive signals indicative of temperature changes in the wells.
